(19) United States
(12) Patent Application Publication
(10) Pub. No.: US 2019/0081277 A1
(43) Pub. Date: Mar. 14, 2019

(54) OLED DISPLAY PANEL PACKAGING METHOD

(71) Applicant: Wuhan China Star Optoelectronics Semiconductor Display Technology Co., Ltd., Wuhan, Hubei (CN)

(72) Inventors: Gaozhen WANG, Wuhan, Hubei (CN); Wei YU, Wuhan, Hubei (CN)

(21) Appl. No.: 15/571,026

(22) PCT Filed: Oct. 19, 2017
(86) PCT No.: PCT/CN2017/106929

§ 371 Date: Oct. 31, 2017

(30) Foreign Application Priority Data
Sep. 13, 2017 (CN) 201710824026.1

(51) Int. Cl. H01L 51/52; H01L 51/56

(52) U.S. Cl. CPC H01L 51/5256; H01L 51/56

(57) ABSTRACT

The present disclosure provides an OLED display panel packaging method, depositing the inorganic thin film on the OLED substrate, depositing the barrier film on the inorganic thin film, the barrier film covering the inorganic thin film on the light emitting region and exposing the inorganic thin film on the lead region, and etching the portion of the inorganic thin film not covered by the barrier film to obtain the inorganic barrier layer corresponding to the thin film encapsulation layer; the present disclosure utilizes a barrier film to etch the inorganic thin film to obtain a patterned inorganic barrier layer without using the mask, so that the problem of electrostatic damage caused by the mask plate and film structure damage and particle problems caused by tearing in the mask and OLED substrate separation process can be avoided, increases the reliability of the inorganic barrier, and saves the cost of the mask.

### FIELD OF THE DISCLOSURE

The present disclosure relates to a flat panel display technology field, and more particularly to an OLED display panel packaging method.

BACKGROUND OF THE DISCLOSURE

Organic light-emitting diode (OLED) display with self-luminous, high brightness, wide viewing angle, high contrast, flexible, low power consumption and other characteristics, so widely concerned, and as a new generation of display, has begun to gradually replace the traditional LCD display. At present, from the small size of the mobile phone display to large-size high-resolution flat-panel TV applications, OLED display panels have become a high-end symbol.

OLED display technology and the traditional liquid crystal display technology is different, without backlight, using a very thin organic coating and glass substrate, when there is current through, these organic materials will be light. However, due to the organic material is easy to react with water vapor or oxygen, as the organic material based display device, requirements of the packaging of the OLED display are very high. It is generally required to have a water vapor transmission rate (WVTR) of less than 10⁻⁶ g/m²/day at 85 ° C. at 85 RH, therefore, increasing the internal seal ability of the device and isolating as much as possible with the external environment are critical to the stability of the OLED device.

At present, OLED device packaging method mainly packaging on the rigid packaging substrate (such as glass or metal) through the packaging glue. However, this method does not apply to flexible devices, and therefore there are technical solutions for encapsulating OLED devices through stacked thin films. The thin film encapsulation method generally forms a plurality of inorganic barrier layers with inorganic material and good resistance to water and gas barrier on the OLED device on the substrate and forms an organic buffer layer with organic material and good flexibility between the two inorganic barrier layers.

In the above-mentioned thin film package structure, the thin film made of silicon oxide (SiOx), silicon nitride (SiNx), aluminum oxide (Al₂O₃) or the like is commonly used for the inorganic barrier layer, the thin film made of acrylic system, hexamethyldimethylsilyl ether (HMDSO) or the like is commonly used for the organic buffer layer; in the preparation method, the inorganic barrier layer is mainly prepared by chemical vapor deposition (CVD), atomic layer deposition (ALD), plasma enhanced chemical vapor deposition (PECVD), ion beam assisted deposition (IBAD) and other processes; however, the thin film packaging process is more complex. As shown in FIG. 1, the mask 50 is used to form the boundary of the inorganic barrier layer 11 when preparing the inorganic barrier layer 11, however the use of mask 50 will bring a lot of shortcomings, such as the problem of electrostatic damage and the structural damage and particle problems caused by tearing which will have a greater impact on the device packaging effect. As shown in FIG. 2, when the mask plate 50 is separated from the substrate 10, the film structure of the inorganic barrier layer 11 is likely to be damaged, and the particle is generated, thereby affecting the flatness and the compactness of the inorganic barrier layer 11.

How to overcome these problems is an important issue for OLED display technology.

### SUMMARY OF THE DISCLOSURE

The object of the present disclosure is to provide an OLED display panel packaging method. The method without using the mask, can effectively solve the electrostatic damage problems, the film structure damage problems and the particle problems caused by using the mask in the existing thin film packaging process, increasing the reliability of the inorganic barrier and saving the cost of the expensive mask.

In order to achieve the above object, the present disclosure provides an OLED display panel packaging method, including the steps of:

step S1: providing an OLED substrate. The OLED substrate includes a substrate, an OLED layer and a lead layer. The substrate has a light emitting region located at a middle portion and a lead region located at an outer periphery of the light emitting region. The OLED layer is arranged on the light emitting region of the substrate. The lead layer is arranged on the lead region of the substrate and is connected to the OLED layer;

step S2: alternately forming an inorganic thin film and an organic buffer layer on the OLED substrate. The inorganic thin film and the organic buffer layer are alternately laminated on the OLED substrate. The inorganic film is one more layer in the number of layers than the organic buffer layer. The inorganic thin film covers the OLED substrate by depositing the entire surface of the OLED substrate. The organic buffer layer covers the OLED layer above the light emitting region;

step S3 providing a barrier film, wherein the barrier film is adhered to the inorganic film so that the barrier film covers an inorganic thin film on the light emitting region to expose the inorganic thin film on the lead region;

step S4: etching the portion of the inorganic thin film that not covered by the barrier film to obtain an inorganic barrier layer, thereby exposing the lead layer of the lead region to obtain a thin film encapsulation layer including the inorganic barrier layer and the organic buffer layer.

The organic buffer layer is formed by the method of ink jet printing in the step S2.

The inorganic thin film is formed in the step S2 using chemical vapor deposition, atomic layer deposition or physical vapor deposition.

The portion of the inorganic thin film not covered by the barrier film is etched by dry etching in the step S4.

The material of the barrier film provided in the step S3 is an organic material.

The material of the inorganic thin film deposited in the step S2 is silicon oxide, silicon nitride, or aluminum oxide.

The step S4 further includes removing the barrier film from the inorganic barrier layer after etching the portion of the inorganic film not covered by the barrier film.

The area of the inorganic barrier layer is larger than the area of the organic buffer layer in the step S4 of forming the thin film encapsulation layer, and each organic buffer layer is sandwiched between two inorganic barrier layers.

The exposed lead layer is used for electrical connection with the external circuit in the step S4.

The substrate is a glass substrate or a polyimide substrate.

The present disclosure also provides an OLED display panel packaging method, including the steps of:

step S1: providing an OLED substrate. The OLED substrate includes a substrate, an OLED layer and a lead layer. The substrate has a light emitting region located at a middle portion and a lead region located at an outer periphery of the light emitting region. The OLED layer is arranged on the light emitting region of the substrate. The lead layer is arranged on the lead region of the substrate and is connected to the OLED layer;

step S2: alternately forming an inorganic thin film and an organic buffer layer on the OLED substrate. The inorganic thin film and the organic buffer layer are alternately laminated on the OLED substrate. The inorganic film is one more layer in the number of layers than the organic buffer layer. The inorganic thin film covers the OLED substrate by depositing the entire surface of the OLED substrate. The organic buffer layer covers the OLED layer above the light emitting region;

step S3: providing a barrier film, wherein the barrier film is adhered to the inorganic film so that the barrier film covers an inorganic thin film on the light emitting region to expose the inorganic thin film on the lead region;

step S4: etching the portion of the inorganic thin film that not covered by the barrier film to obtain an inorganic barrier layer, thereby exposing the lead layer of the lead region to obtain a thin film encapsulation layer including the inorganic barrier layer and the organic buffer layer;

the organic buffer layer is formed by the method of ink jet printing in the step S2;

the inorganic thin film is formed in the step S2 using chemical vapor deposition, atomic layer deposition or physical vapor deposition;

the portion of the inorganic thin film not covered by the barrier film is etched by dry etching in the step S4;

the step S4 further includes removing the barrier film from the inorganic barrier layer after etching the portion of the inorganic film not covered by the barrier film;

the area of the inorganic barrier layer is larger than the area of the organic buffer layer in the step S4 of forming the thin film encapsulation layer, and each organic buffer layer is sandwiched between two inorganic barrier layers.

Advantageous effects of the present disclosure; the OLED display panel packaging method of the present disclosure is a method in which the inorganic thin film depositing on the OLED substrate first, and then depositing the barrier film on the inorganic thin film, so that the barrier film covering the inorganic thin film on the light emitting region and exposing the inorganic thin film on the lead region, finally, the barrier film being the shielding layer, and etching the portion of the inorganic thin film not covered by the barrier film to obtain the inorganic barrier layer corresponding to the thin film encapsulation layer; the present disclosure utilizes a barrier film to etch the inorganic thin film to obtain a patterned inorganic barrier layer without using the mask, so that the problem of electrostatic damage caused by the mask plate and film structure damage and particle problems caused by tearing in the mask and OLED substrate separation process can be avoided, increases the reliability of the inorganic barrier, and saves the cost of the expensive mask.

For the purpose of further understanding the features and technical aspects of the present disclosure, reference is made to the following detailed description of the disclosure and the accompanying drawings, wherein the drawings are provided for the purpose of reference only and are not intended to be limiting of the disclosure.

### BRIEF DESCRIPTION OF THE DRAWINGS

The technical aspects of the present disclosure and other advantageous effects will be apparent from the following detailed description of specific embodiments of the disclosure taken in conjunction with the accompanying drawings.

FIG. 1-2 is a schematic diagram of using the mask to form the inorganic barrier layer in the existing thin film packaging process;

FIG. 3 is a schematic flow diagram of the OLED display panel packaging method of the present disclosure;

FIG. 4 is a schematic diagram of the step S1 of the OLED display panel packaging method of the present disclosure;

FIG. 5-7 is a schematic diagram of the step S2 of the OLED display panel packaging method of the present disclosure;

FIG. 8 is a schematic diagram of the step S3 of the OLED display panel packaging method of the present disclosure;

FIG. 9 is a schematic diagram of the step S4 of the OLED display panel packaging method of the present disclosure.

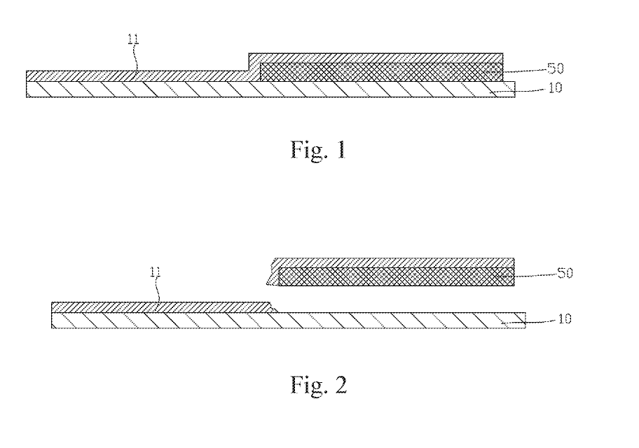

### DETAILED DESCRIPTION OF PREFERRED EMBODIMENTS

The technical means and the effects thereof will be further elucidated with reference to the preferred embodiments of the present disclosure and their accompanying drawings.

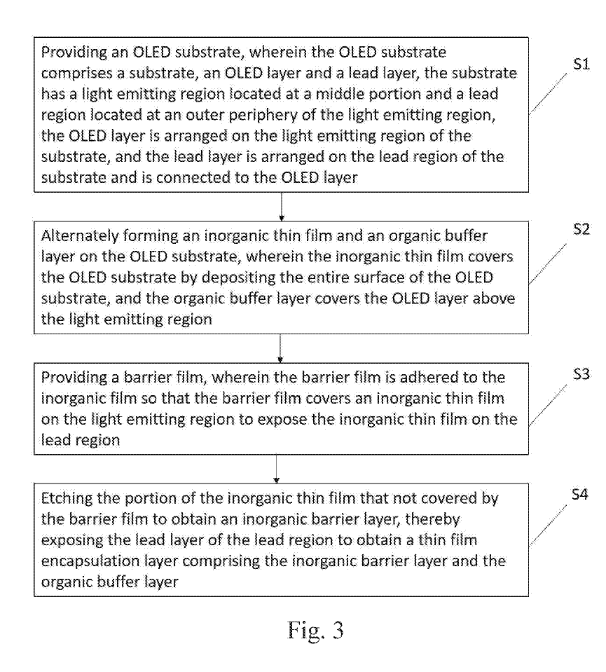

Referring to FIG. 3, the present disclosure provides an OLED display panel packaging method, including the steps of:

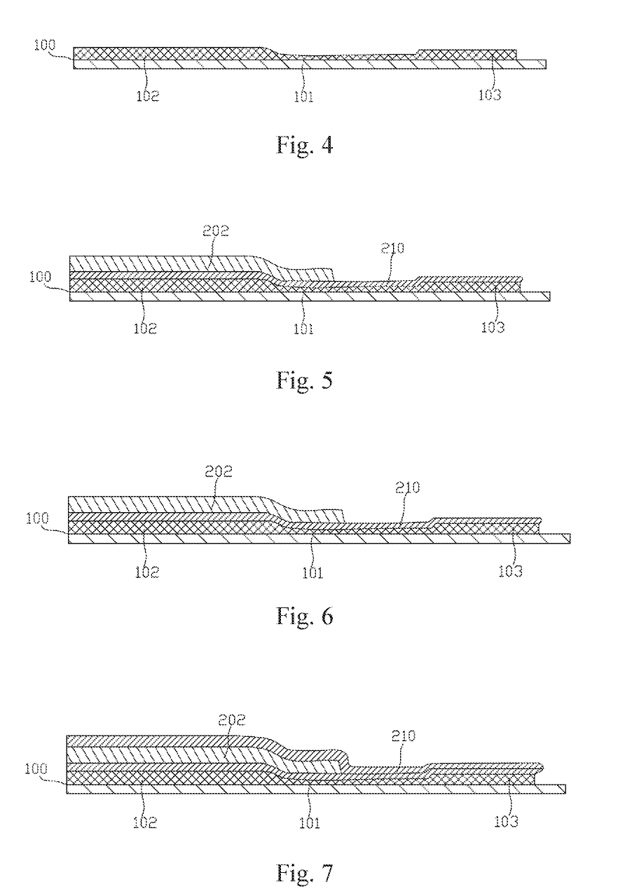

Step S1: providing an OLED substrate 100, as shown in FIG. 4. The OLED substrate 100 includes a substrate 101, an OLED layer 102 and a lead layer 103. The substrate 101 has a light emitting region located at a middle portion and a lead region located at an outer periphery of the light emitting region. The OLED layer 102 is arranged on the light emitting region of the substrate. The lead layer 103 is arranged on the lead region of the substrate 101 and is connected to the OLED layer 102.

Specifically, the substrate 101 is a glass substrate or a flexible polyimide (PI) substrate.

Step S2: whole surface depositing the inorganic thin film 210 on the OLED substrate 100, and before forming the adjacent two-layer inorganic film 210, forming an organic buffer layer 202 overlying the light emitting region over the OLED layer 102 on the inorganic thin film 210 located on the lower layer, as shown in FIGS. 5 to 7; that is, the inorganic thin film 210 and the organic buffer layer 202 are alternately formed on the OLED substrate 100. The inorganic thin film 210 and the organic buffer layer 202 are alternately laminated on the OLED substrate 100. The inorganic thin film 210 is made to have a layer larger than the organic buffer layer 202. The inorganic thin film 210 covers the OLED substrate 100 by the entire surface deposition on the OLED substrate 100. Specifically, two layers of the inorganic thin film 210 are deposited in the step S2. In this step S2, de positing an inorganic thin film 210 on the entire surface of the OLED substrate 100 first, forming an organic buffer layer 202 on the inorganic thin film 201, and then depositing the second layer of the inorganic thin film 210 on the organic buffer layer 202 and the first layer of the inorganic thin film 210.

Specifically, the organic buffer layer 202 is formed by the method of inkjet printing (IJP) in step S2. Since the IJP process itself can control the pattern of the film, the organic buffer layer 202 formed in the step S2 does not require the use of a mask to print out the corresponding pattern so as to ensure the organic buffer layer 202 covering the OLED layer 102 over the light emitting region without covering the lead layer 103 of the lead region.

Specifically, the inorganic thin film is formed in the step S2 using chemical vapor deposition, atomic layer deposition or physical vapor deposition. Since the inorganic thin film 210 is formed on the entire surface deposition, that is, the film formation range is the entire OLED substrate 100, it is not necessary to use the mask plate in this step S2.

Specifically, the material of the inorganic thin film 210 deposited in the step S2 is silicon oxide, silicon nitride, or aluminum oxide.

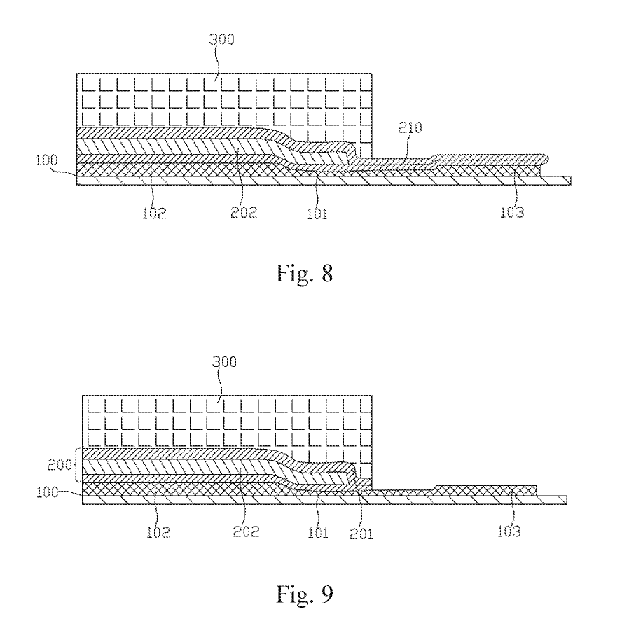

Step 53: providing a suitable barrier film 300, as shown in FIG. 8. The barrier film 300 is adhered to the inorganic film 210 so that the barrier film 300 covers the inorganic thin film 210 on the light emitting region to expose the inorganic thin film 210 on the lead region.

Specifically, the material of the barrier film 300 provided in the step S3 is an organic material.

Step S4: the barrier film 300 is a shielding layer. The inorganic thin film 210 exposed by the barrier film 300 is etched away, as shown in FIG. 9. That is, etching the portion of the inorganic thin film 210 that not covered by the barrier film 300 to obtain the inorganic barrier layer 201, thereby exposing the lead layer 103 of the lead region to obtain the thin film encapsulation layer 200 including the inorganic barrier layer 201 and the organic buffer layer 202.

Specifically, the portion of the inorganic thin film 210 not covered by the barrier film 300 is etched by dry etching in the step S4.

Specifically, the step S4 further includes removing the barrier film 300 from the inorganic barrier layer 210 after etching the portion of the inorganic film 210 not covered by the barrier film 300.

Specifically, the area of the inorganic barrier layer 201 is larger than the area of the organic buffer layer 202 in the step S4 of forming the thin film encapsulation layer 200. and each organic buffer layer 202 is sandwiched between two inorganic barrier layers 201.

Specifically, the lead layer 103 exposed by the inorganic barrier layer 201 is used for electrical connection with the external circuit in the step S4.

The present disclosure utilizes a barrier film 300 to etch the inorganic thin film 210 to obtain a patterned inorganic barrier layer 201 without using the mask, so that the problem of electrostatic damage caused by the mask plate and film structure damage and particle problems caused by tearing in the mask and OLED substrate 100 separation process can be avoided, increases the reliability of the inorganic barrier 201, and saves the cost of the expensive mask.

As described above, the OLED display panel packaging method of the present disclosure is a method in which the inorganic thin film depositing on the OLED substrate first, and then depositing the barrier film on the inorganic thin film, so that the barrier film covering the inorganic thin film on the light emitting region and exposing the inorganic thin film on the lead region, finally, the barrier film being the shielding layer, and etching the portion of the inorganic thin film not covered by the barrier film to obtain the inorganic barrier layer corresponding to the thin film encapsulation layer; the present disclosure utilizes a barrier film to etch the inorganic thin film to obtain a patterned inorganic barrier layer without using the mask, so that the problem of electrostatic damage caused by the mask plate and film structure damage and particle problems caused by tearing in the mask and OLED substrate separation process can be avoided, increases the reliability of the inorganic barrier, and saves the cost of the expensive mask.

As described above, it will be apparent to those skilled in the art that various other changes and modifications may be made in accordance with the technical and technical teachings of the disclosure, and all such changes and modifications are intended to be within the scope of the appended claims appended hereto.

What is claimed is:

1. An OLED display panel packaging method, comprising the steps of:
step S1: providing an OLED substrate, wherein the OLED substrate comprises a substrate, an OLED layer and a lead layer, the substrate has a light emitting region located at a middle portion and a lead region located at an outer periphery of the light emitting region, the OLED layer is arranged on the light emitting region of the substrate, and the lead layer is arranged on the lead region of the substrate and is connected to the OLED layer;
step S2: alternately forming an inorganic thin film and an organic buffer layer on the OLED substrate, wherein the inorganic thin film and the organic buffer layer are alternately laminated on the OLED substrate, the inorganic film is one more layer in the number of layers than the organic buffer layer, the inorganic thin film covers the OLED substrate by depositing the entire surface of the OLED substrate, and the organic buffer layer covers the OLED layer above the light emitting region;
step S3: providing a barrier film, wherein the barrier film is adhered to the inorganic film so that the barrier film covers an inorganic thin film on the light emitting region to expose the inorganic thin film on the lead region;
step 54: etching the portion of the inorganic thin film that not covered by the barrier film to obtain an inorganic barrier layer, thereby exposing the lead layer of the lead region to obtain a thin film encapsulation layer comprising the inorganic barrier layer and the organic buffer layer.

2. The OLED display panel packaging method according to claim 1, wherein the organic buffer layer is formed by the method of ink jet printing in the step S2.

3. The OLED display panel packaging method according to claim 1, wherein the inorganic thin film is formed in the step S2 using chemical vapor deposition, atomic layer deposition or physical vapor deposition.

4. The OLED display panel packaging method according to claim 1, wherein the portion of the inorganic thin film not covered by the barrier film is etched by dry etching in the step S4.

5. The OLED display panel packaging method according to claim 1, wherein the material of the barrier film provided in the step S3 is an organic material.

6. The OLED display panel packaging method according to claim 1, wherein the material of the inorganic thin film deposited in the step S2 is silicon oxide, silicon nitride, or aluminum oxide.

7. The OLED display panel packaging method according to claim 1, wherein the step S4 further comprises removing the barrier film from the inorganic barrier layer after etching the portion of the inorganic film not covered by the barrier film.

8. The OLED display panel packaging method according to claim 1, wherein the area of the inorganic barrier layer is larger than the area of the organic buffer layer in the step S4 of forming the thin film encapsulation layer, and each organic buffer layer is sandwiched between two inorganic barrier layers.

9. The OLED display panel packaging method according to claim 1, wherein the exposed lead layer is used for electrical connection with the external circuit in the step S4.

10. The OLED display panel packaging method according to claim 1, wherein the substrate is a glass substrate or a polyimide substrate.

11. An OLED display panel packaging method, comprising the steps of:
step S1: providing an OLED substrate, wherein the OLED substrate comprises a substrate, an OLED layer and a lead layer, the substrate has a light emitting region located at a middle portion and a lead region located at an outer periphery of the light emitting region, the OLED layer is arranged on the light emitting region of the substrate, and the lead layer is arranged on the lead region of the substrate and is connected to the OLED layer;
step S2: alternately forming an inorganic thin film and an organic buffer layer on the OLED substrate, wherein the inorganic thin film and the organic buffer layer are alternately laminated on the OLED substrate, the inorganic film is one more layer in the number of layers than the organic buffer layer, the inorganic thin film covers the OLED substrate by depositing the entire surface of the OLED substrate, and the organic buffer layer covers the OLED layer above the light emitting region;
step S3: providing a barrier film, wherein the barrier film is adhered to the inorganic film so that the barrier film covers an inorganic thin film on the light emitting region to expose the inorganic thin film on the lead region;
step S4: etching the portion of the inorganic thin film that not covered by the barrier film to obtain an inorganic barrier layer, thereby exposing the lead layer of the lead region to obtain a thin film encapsulation layer comprising the inorganic barrier layer and the organic buffer layer;
wherein the organic buffer layer is formed by the method of ink jet printing in the step S2;
wherein the inorganic thin film is formed in the step S2 using chemical vapor deposition, atomic layer deposition or physical vapor deposition;
wherein the portion of the inorganic thin film not covered by the barrier film is etched by dry etching in the step S4;
wherein the material of the barrier film provided in the step S3 is an organic material;
wherein the material of the inorganic thin film deposited in the step S2 is silicon oxide, silicon nitride, or aluminum oxide;
wherein the step S4 further comprises removing the barrier film from the inorganic barrier layer after etching the portion of the inorganic film not covered by the barrier film;
wherein the area of the inorganic barrier layer is larger than the area of the organic buffer layer in the step S4 of forming the thin film encapsulation layer, and each organic buffer layer is sandwiched between two inorganic barrier layers.

12. The OLED display panel packaging method according to claim 11, wherein the material of the barrier film provided in the step S3 is an organic material.

13. The OLED display panel packaging method according to claim 11, wherein the material of the inorganic thin film deposited in the step S2 is silicon oxide, silicon nitride, or aluminum oxide.

14. The OLED display panel packaging method according to claim 11, wherein the exposed lead layer is used for electrical connection with the external circuit in the step S4.

15. The OLEO display panel packaging method according to claim 11, wherein the substrate is a glass substrate or a polyimide substrate.
